(19) United States
(12) Patent Application Publication
(10) Pub. No.: US 2014/0127912 A1
(43) Pub. Date: May 8, 2014

(54) PLASMA PROCESS ETCH-TO-DEPOSITION RATIO MODULATION VIA GROUND SURFACE DESIGN

(71) Applicants: Liqi Wu, Santa Clara, CA (US); Ishtak Karim, San Jose, CA (US); Huatan Qiu, Dublin, CA (US)

(72) Inventors: Liqi Wu, Santa Clara, CA (US); Ishtak Karim, San Jose, CA (US); Huatan Qiu, Dublin, CA (US)

(21) Appl. No.: 13/672,552

(22) Filed: Nov. 8, 2012

(51) Int. Cl. H01L 21/02

(52) U.S. Cl. CPC H01L 21/02
USPC 438/758; 118/723 R; 118/696

(57) ABSTRACT

Plasma deposition in which properties of a discharge plasma are controlled by modifying the grounding path of the plasma is potentially applicable in any plasma deposition environment, but finds particular use in ionized physical vapor deposition (iPVD) gapfill applications. Plasma flux ion energy and E/D ratio can be controlled by modifying the grounding path (grounding surface's location, shape and/or area). Control of plasma properties in this way can reduce or eliminate reliance on conventional costly and complicated RF systems for plasma control. For a high density plasma source, the ionization fraction and ion energy can be high enough that self-sputtering may occur even without any RF bias. And unlike RF induced sputtering, self-sputtering has narrow ion energy distribution, which provides better process controllability and larger process window for integration.

### FIELD OF THE INVENTION

The present invention pertains to methods and apparatus for plasma deposition. In particular, the present invention pertains to plasma deposition-etch processing. The methods and apparatus are particularly useful for deposition-etch processing conducted in semiconductor fabrication.

### BACKGROUND OF THE INVENTION

Miniaturization of integrated circuit (IC) devices demands superior electrical properties from both dielectric and conductive materials used in the manufacturing of an integrated circuit. Copper, due to its lower resistivity, has replaced aluminum as a conducting material in many IC applications, while dielectric materials with low dielectric constant (low-k and ultra low-k dielectrics) have replaced the traditionally used silicon dioxide as an inter-layer dielectric (ILD) material. The low-k dielectric materials now used in the IC device processing include carbon doped silicon dioxide, hydrogenated silicon oxycarbides (SiCOH), fluorine doped silicon dioxide, and organic-containing low-k dielectrics. These materials, due to their low dielectric constants, provide low parasitic capacitance and minimize the “crosstalk” between the interconnects in an integrated circuit. At the same time, they are often porous foam-like materials and are generally more easily damaged during the processing steps compared to more robust silicon dioxide.

Currently used IC fabrication processes often include operations that both deposit and remove or redistribute material on a wafer surface using ions generated in a plasma. These operations typically include deposition and etch components. Typically in such methods, positively charged inert gas ions or metal ions impinge on a negatively RF biased substrate, depositing, removing or redistributing portions of exposed material residing on a wafer substrate. Examples of materials that can be deposited, removed or redistributed using plasma deposition and/or etch processing include diffusion barrier materials (e.g., Ta and TaNₓ), and seed layer and fill materials such as copper and its alloys, and copper feature fill.

With ongoing miniaturization of IC devices, especially with processing of devices at a sub-28 nm technology node and at more advanced nodes, it becomes more challenging to perform plasma deposition, particularly feature fill, without exposing dielectric layers to plasma. When plasma deposition is performed under conventional conditions, the exposed dielectric material can easily become damaged by high-energy ions that impinge upon it.

### SUMMARY OF THE INVENTION

The present invention relates to methods and apparatus for plasma deposition in which the properties of the plasma are controlled by modifying the grounding path of the plasma. The invention is potentially applicable in any plasma deposition environment, but finds particular use in ionized physical vapor deposition (iPVD) gap fill applications. According to various aspects of the invention, a discharge plasma is generated in a plasma reactor by ionization of an inert feed gas (typically Ar) and sputtered material from a target. The discharge plasma includes metal and inert gas ions. The plasma circuit includes the target, the plasma itself, a grounding surface in the reactor, typically configured as a plurality of grounding shields, and a power supply that energizes the target. It has been found that the energy of ions impacting the substrate and etch-to-deposition ratio of the plasma flux can be controlled by modifying the grounding path (grounding surface's location, shape and/or area). Control of plasma properties in this way can reduce or eliminate reliance on conventional complicated RF systems for plasma control. For a high density plasma source, the ionization fraction and ion energy can be high enough that self-sputtering (that is, sputtering caused by substrate floating potential alone) may occur even without any RF bias. The self-sputtering rate and actual E/D ratio can be modulated by adjusting the grounding surface's location, shape and/or area. And unlike RF induced sputtering, self-sputtering has narrow ion energy distribution, which provides better process controllability and larger process window for integration.

In particular embodiments, control of plasma properties by modifying the grounding path of the plasma can be conducted with or without application of RF bias. Even in conjunction with the application of RF bias, self-sputtering induced by grounding path modulation narrows the impacting ion energy distribution, decreasing the likelihood of damage to underlying structures during deposition-etch processing. In some preferred embodiments, RF is completely eliminated, with the resulting benefit of reducing reactor complexity while providing more uniform ion energy distribution for improved performance.

According to specific embodiments, the modifying of the grounding path involves switching between float and ground one or more grounding shields in an array of switched grounding shields in the plasma reactor. The grounding shields in the array are electrically isolated from each other and vary in surface area and location relative to the wafer support. At least one of the switched shields of the array is grounded to sustain a discharge.

According to other specific embodiments, the modifying of the grounding path comprises varying (e.g., with a potentiometer) resistance to ground of a variable grounding shield in conjunction with a grounded shield electrically isolated from the variable grounding shield.

The invention also relates to a plasma deposition apparatus. The apparatus includes a processing chamber, a deposition substrate support, a metal ion discharge plasma source, and a plurality of grounding shields. The grounding shields are configured to control properties of the discharge plasma by modifying the grounding path of the discharge plasma. In some embodiments, the grounding shields are configured as an array of switched shields having different surface area and location relative to the wafer support, wherein at least one of the switched shields of the array is grounded. In other embodiments, the grounding shields are configured as at least two shields, one of which is grounded and the other(s) having variable resistance to ground. In various embodiments, the apparatus may or may not include an RF system.

The provided apparatus can further include a controller comprising program instructions for implementing methods described herein. Accordingly, the apparatus may be specifically configured to perform the methods described herein. As such, the controller may be programmed with instructions specifying parameters for generating a discharge plasma in which the properties of the plasma are controlled by modifying the grounding path of the plasma. For example, in an apparatus in which the grounding shields are configured as an array of switched shields having different surface area and location relative to the wafer support, the controller may comprise program instructions for switching between float and ground one or more grounding shields in the array. Or, in an apparatus in which the grounding shields are configured as at least two shields, one of which is grounded and the other(s) having variable resistance to ground, the controller may comprise program instructions for varying resistance to ground of the variable grounding shield(s).

These and other features and advantages of the present invention will be described in more detail below with reference to the associated drawings.

### BRIEF DESCRIPTION OF THE DRAWINGS

FIGS. 1A-1F show cross sectional depictions of device structures created during a copper dual Damascene fabrication process.

FIG. 2 is a cross sectional depiction of a hollow cathode magnetron (HCM) apparatus in accordance with the present invention.

FIG. 3, shows a particular embodiment of a shield configuration in accordance with the present invention is illustrated in top plan view and cross-section.

FIG. 4, shows an alternative embodiment of a shield configuration in accordance with the present invention is illustrated in cross-section.

FIG. 5 presents a process flow diagram for processes in accordance with the present invention.

FIGS. 6A-6B show cross-sectional views of device structures during PVD metal fill in accordance with one embodiment of the invention.

FIGS. 7A-7E show cross-sectional views of device structures during PVD metal fill in accordance with another embodiment of the invention.

FIGS. 8A-8B show representative plasma sheath potentials in the case RF bias is applied (8A) and in the case the same average sheath potential is achieved without RF bias using plasma grounding path modification (8B).

### DETAILED DESCRIPTION OF SPECIFIC EMBODIMENTS

As noted above, the present invention relates to methods and apparatus for plasma deposition in which the properties of the plasma are controlled by modifying the grounding path of the plasma. The invention is potentially applicable in any plasma deposition environment, but finds particular use for filling recessed features on semiconductor substrates, for example by ionized physical vapor deposition (iPVD). According to various aspects of the invention, a discharge plasma is generated in a plasma reactor by ionization of a feed gas and sputtered material from a target. The discharge plasma includes metal and inert gas ions. The plasma circuit includes the target, the plasma itself, a grounding surface in the reactor, typically configured as a plurality of grounding shields, and a power supply that energizes the target. It has been found that the energy of ions impacting the substrate and etch-to-deposition ratio of the plasma flux can be controlled by modifying the grounding path (grounding surface's location, shape and/or area). Control of plasma properties in this way can reduce or eliminate reliance on conventional complicated RF systems for plasma control. For a high density plasma source, the ionization fraction and ion energy can be high enough that self-sputtering (that is, sputtering caused by substrate floating potential alone) may occur even without any RF bias. The self-sputtering rate and actual etch-to-deposition (E/D) ratio can be modulated by adjusting the grounding surface's location, shape and/or area. And unlike RF induced sputtering, self-sputtering has narrow ion energy distribution, which provides better process controllability and larger process window for integration.

The described methods can be used for depositing a variety of metals which include but are not limited to copper, aluminum, titanium, silver, tantalum, tungsten and molybdenum. The methods can be also used for partially or completely filling recessed features with metal alloys, such as copper alloys and aluminum alloys. For example, alloys of copper or aluminum with certain metals and non-metallic elements are used to improve electromigration performance of IC devices (e.g., Cu—Ti alloy). Further, some alloys may be deposited directly onto dielectric to self-form diffusion barrier layers. For example, alloys of copper with magnesium or with manganese can provide self-forming diffusion barrier layers, due to oxidation of Mg or Mn on the surface of dielectric. In general a variety of alloys may be deposited using described methods, including Cu—Mg, Cu—Mn, Cu—Al, Al—Si, etc. A PVD target made of a suitable metal alloy can be used for alloy deposition according to the provided methods. The methods may be used for partially or completely filling different types of recessed features, such as trenches, vias, and contact holes. The methods enable improved metal fill by a variety of plasma deposition techniques using capacitive and/or inductive plasmas, including plasma enhanced chemical vapor deposition (PECVD) and high density plasma chemical vapor deposition (HDP-CVD), but are particularly applicable to physical vapor deposition (PVD), specifically by plasma PVD (ionized PVD or iPVD). As such, while the invention is applicable beyond iPVD, it primarily described herein with reference to iPVD.

In order to frame the context of this invention, a brief description of a copper dual Damascene process for forming a partially fabricated integrated circuit is described below. The presented methods are not limited to a dual Damascene process and can be used in other processing methods, e.g., in single Damascene processing. While provided methods are particularly advantageous for processing substrates having relatively narrow recessed features with widths of about 300 nm and less (e.g., in the range of about 20-300 nm, such as 28 nm), they can be equally well applied to filling wider recesses.

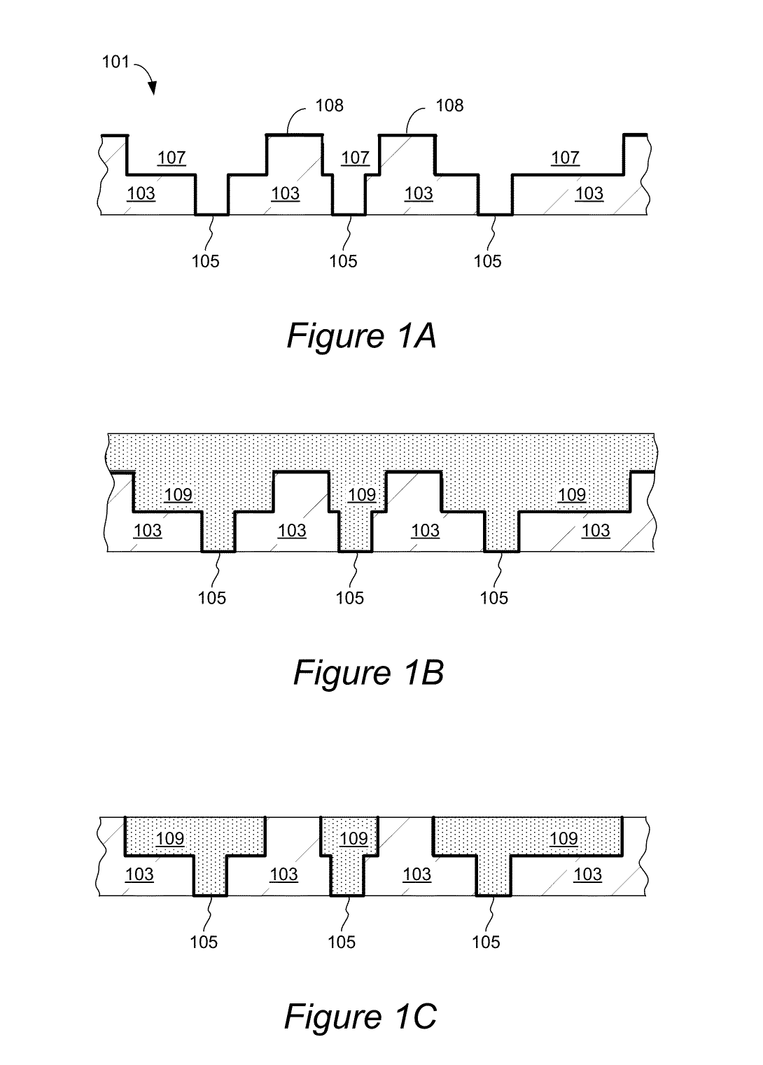

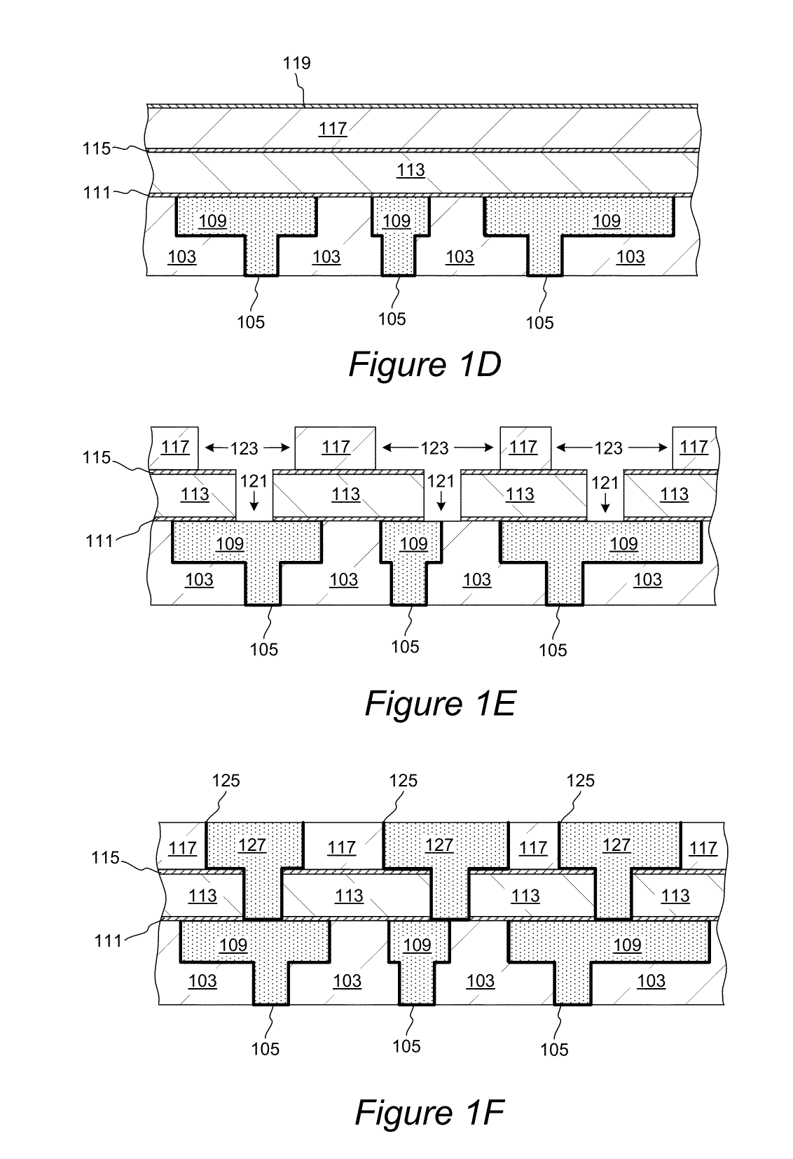

Presented in FIGS. 1A-1E, is a cross sectional depiction of device structures created at various stages of a dual Damascene fabrication process. A cross sectional depiction of a completed structure created by the dual Damascene process is shown in FIG. 1F. Referring to FIG. 1A, an example of a typical substrate 101 used for dual Damascene processing is illustrated. The substrate 101 may reside on a layer carrying active devices, such as transistors, or on an underlying metallization layer containing copper lines or other type of metallization. The substrate 101 is built on a semiconductor wafer and is therefore referred to as a semiconductor substrate. The term semiconductor substrate, as used herein, refers to a substrate which contains a semiconductor material anywhere within the structure.

Substrate 101 includes a pre-formed dielectric layer 103 (such as fluorine or carbon doped silicon dioxide or organic-containing low-k material) with etched line paths 107 (trenches and vias) and a field region 108. A thin diffusion barrier layer 105 is deposited conformally to coat the substrate surface both within the recesses and on the field. Diffusion barrier material is needed to protect the dielectric layer 103 and underlying active devices from diffusion of copper atoms. Suitable diffusion barrier materials include tantalum, tantalum nitride, titanium nitride, titanium tungsten, and the like. In a typical process, barrier 105 is formed by a physical vapor deposition (PVD) method, although atomic layer deposition (ALD) and chemical vapor deposition (CVD) may also be used. In an alternative process flow, the PVD metal fill methods described herein may be used to deposit a self-forming diffusion barrier layer (e.g., a Cu—Mg, or Cu—Mn alloy) directly onto the dielectric layer, and, if desired, to proceed with filling the recessed feature with such alloy. Magnesium and manganese are capable of forming a layer of oxide on the surface of dielectric, and to thereby prevent diffusion of copper into an adjacent dielectric layer.

Returning to the process flow depicted in FIG. 1A, after the copper diffusion barrier layer 105 has been deposited, the recessed features 107 are filled with copper. Conventionally used methods required deposition of a thin conformal copper seed layer on top of barrier layer 105, followed by electrodeposition of bulk copper to fill the recesses 107. This two-step operation requires substrate transfer from a PVD apparatus where the barrier and seed layers were deposited to a copper electrofill apparatus, where the recesses 107 are filled. This necessarily exposed the partially fabricated substrate to ambient atmosphere and to wet chemistry that is used during electrofill operation. Alternatively, PVD copper fill can be performed in a dry vacuum environment using plasma PVD process chamber, without exposing the substrate to ambient atmosphere, and without requiring deposition of a seed layer. Thus, the vias and trenches may be filled with copper immediately after the copper diffusion barrier layer 105 has been deposited. For example, the substrate may be transferred from a tantalum or titanium PVD chamber used for diffusion barrier deposition to a copper PVD chamber for copper PVD fill. In some embodiments, the transfer can be done in one PVD system containing multiple PVD chambers without exposing the substrate to an ambient atmosphere containing moisture and oxygen.

Typically, etching and depositing processes occur simultaneously in the PVD chamber. Etching is performed by the inert gas ions and, in some cases, by metal ions, impinging on the wafer with sufficient energy to dislodge the exposed material, while deposition is effected by neutral metal atoms and, in some cases, by metal ions, being sputtered onto the wafer from the target. When an intrinsic etch rate E is greater than the intrinsic deposition rate D, a net etching process occurs on the wafer surface. When the etch rate E is smaller than the deposition rate D, the process is characterized as a net deposition. An etch rate to deposition rate ratio is often used to characterize the combined process. At the E/D ratio of 1, no net deposition or etching occurs. At the E/D ratio of 0, the process is pure deposition. It is important to be able to control and modulate the E/D ratio in order to tailor or optimize deposition characteristics of a plasma flux for particular applications.

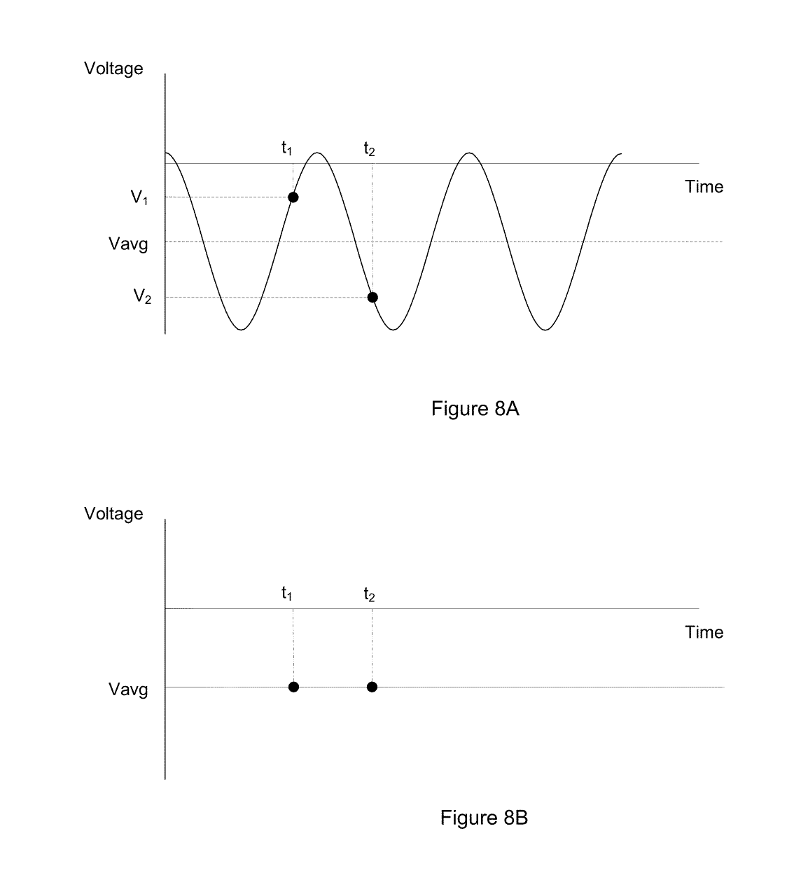

Despite the many disadvantages of deposition flux modulation using RF bias application to the wafer, it is a standard technique for etch-to-deposition (E/D) ratio modulation inside a PVD chamber. Application of RF bias to enhance the ion energy of the plasma flux is widely employed in semiconductor fabrication processes. However, the RF bias technique suffers from lack of ion energy control since the ions that are accelerated in the plasma sheath (thin region between the plasma and substrate) encounter varying electric fields depending on when, i.e., at what part of the RF cycle, a particular ion enters the sheath. For typical plasma species and conditions found in semiconductor processing environments, e.g., DC discharge PVD Cu with Ar feed gas, the transit time of the ions through the sheath is substantially shorter than the RF cycle. A given ion, therefore, sees an approximately constant electric field determined by the period in the RF cycle in traveling from the top of the sheath to the substrate. For example, as depicted in FIG. 8A, ion₁ that enters the sheath at time t₁ will experience a voltage V₁>V_{avg} approximately throughout its presence in the sheath while ion₂ that enters the sheath at time t₂ will experience a voltage V₂<V_{avg} approximately throughout its presence in the sheath. Every ion sees a different approximately constant electric field giving rise to a wide energy distribution. The width and shape of the distribution can be somewhat controlled using different RF frequencies and waveforms, but there will be a substantially finite width in all cases with RF bias. The resulting deposition plasma flux with the desired average ion energy will necessarily include unwanted higher energy ions that may damage the substrate and lower energy ions that may not have the required deposition characteristics (e.g., insufficient etch rate to prevent overhang formation).

An RF modulated plasma deposition process, therefore, leads to wide ion energy distribution in the plasma flux. Since both sputter yield and angle depend on incident ion energy, they too have a wide distribution in these circumstances. Ions that have high energy tend to cause substrate damage, while random sputter angle generally causes overhang at the structure's opening area. Both substrate damage and overhang cause major integration issues, such as poor adhesion, impurity, high line resistance, and degraded gapfill. Therefore, PVD process window is limited by wide energy distribution of the incident ions, and PVD extendibility for aggressive sub-28 nm technologies is jeopardized.

In addition, the implementation of an RF system is a challenge for reactor module manufacturability and reliability. RF delivery is a general issue for PVD chamber matching, and the complicated RF system adds to the tool's cost.

Therefore, a plasma deposition technology that can narrow the incident ion energy distribution and/or potentially eliminate the need for an RF system while maintaining E/D ratio modulation capability is desirable from both technology and engineering perspectives.

The present invention provides new plasma deposition methods that minimize these problems and allow direct PVD fill of recessed features with widths of less than about 300 nm, less than about 100 nm, and even less than about 50 nm, e.g., sub 28 nm technologies. Recessed features with aspect ratios of greater than 2:1, and even 5:1 or more can be filled. As a result, PVD copper fill can be successfully integrated into Damascene process at current and future levels of miniaturization, at least for some metallization layers. Detailed description of PVD deposition conditions and process parameters used by these methods will be provided in the following sections. As noted previously, while the methods and apparatus of the present invention are primarily described with reference to iPVD, the principles are applicable to any plasma-based deposition technique where RF bias can be reduced or eliminated by modulation of plasma characteristics (e.g., E/D ratio) as described herein.

The invention provides a method to modulate process etch-to-deposition (E/D) ratio via grounded shield surface design, which can narrow the incident ion energy distribution and potentially eliminate traditional complicated RF system on an iPVD or other plasma deposition process module. The deposition substrate bias (i.e., wafer floating potential V_{f}) and ion energy (i.e., the difference between floating potential and plasma potential V_{f}−Vₚ) inside a PVD deposition chamber typically depends on the plasma circuit grounding surface's location, shape, and area. For a high density plasma source, the ionization fraction and ion energy can be high enough that self-sputtering (that is, sputtering caused by substrate floating potential alone) may occur with reduced or even without RF bias. The self-sputtering rate and actual E/D ratio can be modulated by adjusting the plasma's grounding path (e.g., the location, shape and/or area of the grounding surface). Self-sputtering has narrow ion energy distribution, which provides better process controllability and larger process window for integration.

Unlike using RF bias to energize the sheath and incident ions, sheath potential and incident ion energy modulation using plasma grounding path modification results in time independent (i.e., DC) values. Since the sheath potential in this case is not driven by any RF and is a direct function of quiescent plasma electron temperature, no inherent source of time dependence exists. This is, of course, if the said modification is kept constant in time. As will be explained in further detail below, the grounding path modification can also be modulated over time (for example, over the course of the deposition period) in order to modulate the incident ion energy in an appropriate manner during the deposition. If the grounding path modification is kept constant in time, then all ions will experience the same constant sheath potential resulting in a mono-energetic plasma flux. As a parallel example to the RF bias case, FIG. 8B depicts two ions, ion₁ and ion₂, entering the sheath at times t₁ and t₂, respectively. Since the sheath potential is constant in time, both ion₁ and ion₂ will experience the same voltage V_{avg} in this case. The ions will still have a small amount of energy distribution due to the difference in their energies when they enter the sheath (finite ion temperature), but the width of this distribution is practically negligible and certainly much smaller than that if RF bias were applied. Consequently, incident ion energy modulation using plasma grounding path modification enables one to produce a deposition plasma flux with the desired average ion energy without parasitic higher and lower energy ions.

In accordance with the present invention, the self-sputtering rate, and hence the E/D ratio of a deposition plasma is controlled by modifying the grounding path (e.g., the grounding surface's (shields in PVD chamber) location, shape and/or area). In particular embodiments, this is accomplished by, instead of using a single piece of grounding shield or electrically connected shields, using plurality of shields that are electrically insulated from each other. These shields can be either floated or grounded or a combination through electrical circuit control (e.g., switches or a potentiometer, as described further below). The self-sputtering rate and E/D ratio can be varied to increase the deposition or etch characteristic of the plasma flux by varying the grounding of the plurality of shields. In the absence of RF biasing, the bias on the substrate is solely due to the substrate floating potential thereby generating a narrow ion energy distribution.

Returning to FIG. 1B, a copper layer 109 which is deposited into the features with an overburden, resides on top of diffusion barrier layer 105 both over the field and over the filled recesses. All conductive material residing on the field (which includes both copper overburden and diffusion barrier residing on the field) is subsequently removed from the field region to prevent shorting between adjacent interconnects. This is performed by a planarization operation, such as CMP. The resulting planarized structure is shown in FIG. 1C, where it can be seen that diffusion barrier 105 and copper overburden have been removed from the field region and that the dielectric layer 103 is exposed.

In an alternative embodiment, it is possible to arrive directly from the structure shown in FIG. 1A to the structure shown in FIG. 1C, without forming an intermediate structure with copper overburden shown in FIG. 1B. In this embodiment, PVD plasma conditions are adjusted such that copper is deposited within the recesses 107, while diffusion barrier material is simultaneously removed from the field region as a result of plasma etching.

After the structure shown in FIG. 1C is formed, the dual Damascene process follows by building the next metallization layer. As depicted in FIG. 1D, a silicon nitride or silicon carbide diffusion barrier/etch-stop layer 111 is deposited to encapsulate conductive routes 109. Next, a first dielectric layer, 113, of a dual Damascene dielectric structure is deposited on diffusion barrier/etch-stop layer 111. The dielectric 113 is typically a low-k dielectric, such as described above for the layer 103. This is followed by deposition of an etch-stop layer 115 (typically composed of silicon nitride or silicon carbide) on the first dielectric layer 113. Layers 111, 113, and 115 can be deposited by CVD and plasma enhanced CVD (PECVD) methods from a variety of silicon, oxygen, carbon, and nitrogen containing precursors.

The process follows, as depicted in FIG. 1D, where a second dielectric layer 117 of the dual Damascene dielectric structure is deposited in a similar manner to the first dielectric layer 113, onto etch-stop layer 115. Deposition of an antireflective layer 119, typically containing BARC materials, follows.

The dual Damascene process continues, as depicted in FIGS. 1E-1F, with etching of vias and trenches in the first and second dielectric layers. First, vias 121 are etched through antireflective layer 119 and the second dielectric layer 117. Standard lithography techniques are used to etch a pattern of these vias. The etching of vias 121 is controlled such that etch-stop layer 115 is not penetrated. As depicted in FIG. 1E, in a subsequent lithography process, antireflective layer 119 is removed and trenches 123 are etched in the second dielectric layer 117; vias 121 are propagated through etch-stop layer 115, first dielectric layer 113, and diffusion barrier 111.

Next, as depicted in FIG. 1F, these newly formed vias and trenches are coated with a diffusion barrier 125 and are subsequently completely or partially filled with copper using PVD fill methods described herein. When copper fill is performed with overburden, the structure is then planarized to remove the copper overburden and portions of diffusion barrier material 125 (e.g., TaNₓ, TiNₓ, etc.) residing in the field region. Alternatively, PVD fill methods can simultaneously fill the recesses with copper while removing diffusion barrier material from the field region. The completed dual Damascene structure is shown in FIG. 1F, where PVD-deposited copper inlay 127 resides within dielectric and is separated from the dielectric layers 113 and 117 by a diffusion barrier layer 125.

Copper routes 127 and 109 are now in electrical contact and form conductive pathways, as they are separated only by diffusion barrier 125, which is also sufficiently conductive. Three such interconnects are shown in FIG. 1F.

Particular embodiments of plasma deposition, in particular recessed feature fill, methods and apparatus with process etch-to-deposition ratio modulation via ground surface design in accordance with the present invention will be now described in detail.

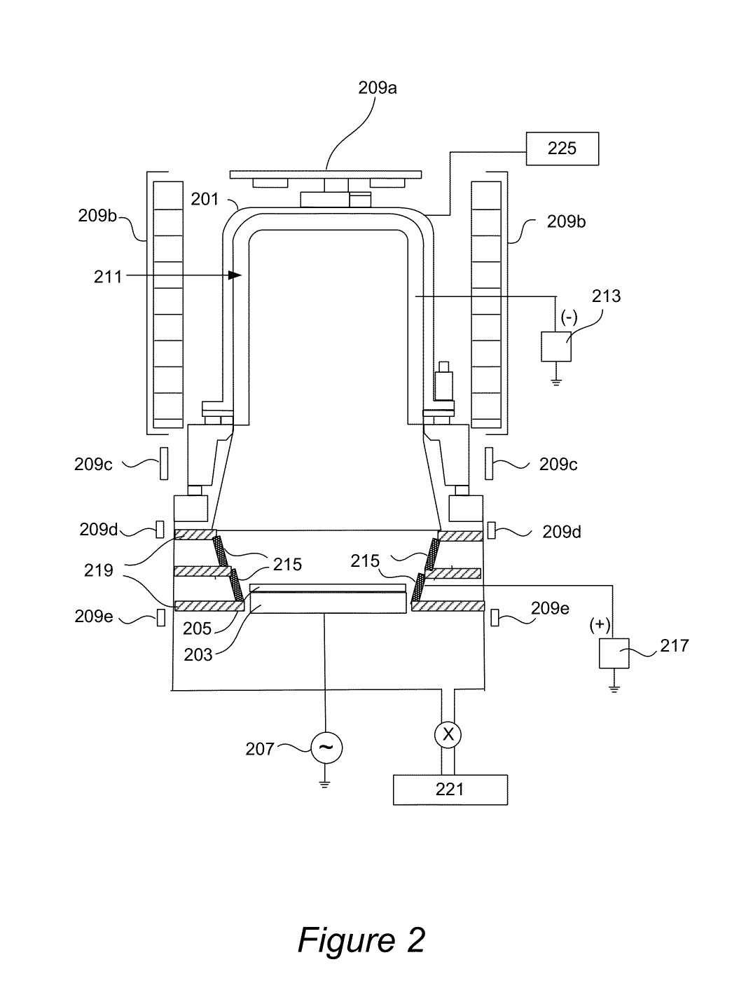

The present invention may be implemented in a variety of plasma apparatus. The invention will be primarily described herein with reference to a DC discharge plasma ionized PVD system, although it is not so limited, and given the principles of the invention described herein, one of skill in the art would understand how to adapt other plasma apparatus and techniques, including AC discharge plasma systems, PECVD systems and HDP-CVD systems, for example, in accordance with the invention. Benefits of the present invention are particularly apparent in DC discharge iPVD feature fill, however. PVD reactor process chambers that include a hollow cathode magnetron or a planar magnetron can be used. FIG. 2 presents a cross sectional view of one type of a hollow cathode magnetron (HCM) sputtering apparatus in accordance with one embodiment of the invention. The HCM apparatus has two main components, the source 201, in which a plasma is created and maintained, and the substrate support (e.g., chuck or wafer pedestal) 203, which secures the wafer 205 (not part of the apparatus, but shown for context). In some embodiments, a separate RF power supply 207 is electrically connected to the wafer pedestal and provides the RF bias to the pedestal 203 when required, leading to generation of an average negative bias at the wafer, upon interaction of the biased wafer with the plasma. In some preferred embodiments, however, deposition is performed without applying an RF bias to the wafer, and there is no need for an RF system, so the cost and operational complexity of the RF system in the apparatus can be avoided. The pedestal 203 also serves to provide the temperature control for the wafer 205. The temperature at the wafer pedestal can range from about −50 to 600° C., preferably between about 0 and 150° C.

In this example, the HCM contains a top rotating magnet 209a, several annular side electromagnets 209b-209e, circumferentially positioned around the process chamber, and a sputter target 211, operated at a negative DC bias. The sputter target is electrically connected to the DC target power supply 213. A DC bias power of between about 1-100 kW is typically applied to the target. The density of plasma in the apparatus can be controlled by controlling magnetic confinement of plasma within the hollow target portion of the HCM and in the vicinity of the wafer. In some embodiments, highly magnetically confined plasma is generated within an HCM by applying an intense magnetic field at the target portion of an apparatus, such as by passing high currents through electromagnetic coils 209b. In a specific example currents greater than about 6 kA-turn are passed through at least some coils to generate a magnetic field of at least about 0.1 Tesla in the vicinity of the target, and to form a plasma having a density of at least about 10¹³ electrons/cm³ within the target region. In other embodiments, the use of ultra-high magnetic fields is not required for a magnetically confined plasma.

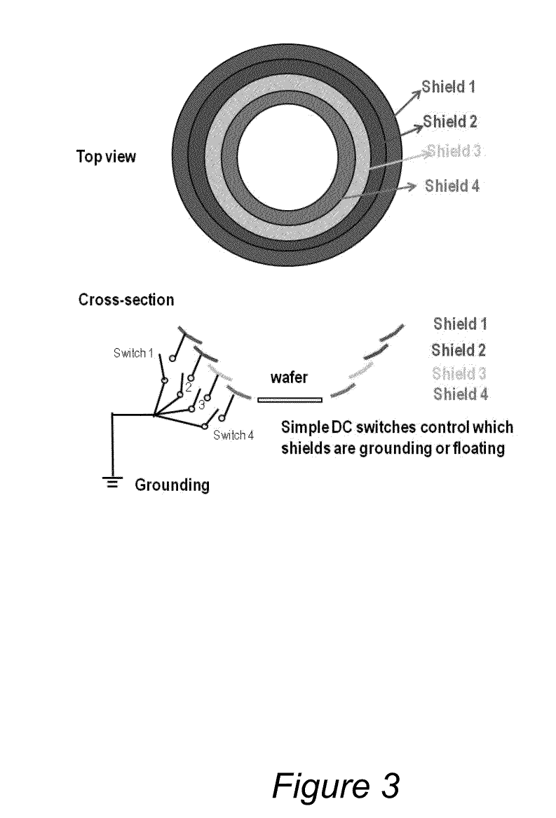

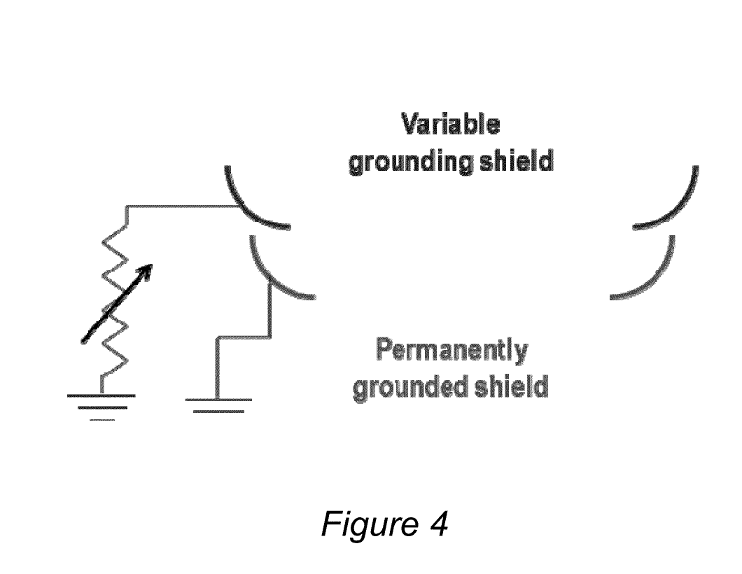

In accordance with the present invention, a plurality of shields is positioned within the chamber next to the chamber sidewalls, to protect the sidewalls from the sputtered material and to provide a DC grounding surface. The shields 215 are electrically isolated from the process chamber sidewalls and each other, for example with insulating ceramic rings 219. As described above and in further detail below, at least one of the plurality of shields is connected to ground source 217, while the other(s) are floated or variably grounded. In the provided example, the shields 615 are aluminum members having a hollow trapezoidal shape, located from about the level of the wafer pedestal 203 to about 30 cm below the target 211. The number and positioning of the shields depicted in FIG. 2 are only representative. Further details of shield configurations are shown in FIGS. 3A-B and FIG. 4, with reference to which particular embodiments of the application are described below.

The cathode target 211 generally has a hollow cup-like shape so that plasma formed in the source can be concentrated within this hollow region. The cathode target 211 also serves as a sputter target and is, therefore, made of a metal material which is to be deposited onto a substrate. For example, a copper target is used for copper fill and aluminum target is used for aluminum fill. A target made of an alloy can be used to fill the features with alloys.

An inert gas, such as argon, is introduced through a gas inlet (not shown to preserve clarity) into the process chamber from the sides, above the pedestal 203. The pump 221 is positioned to evacuate or partially evacuate the process chamber. The control of pressure in the process chamber can be achieved by using a combination of gas flow rate adjustments and pumping speed adjustments, making use of, for example, a throttle valve or a baffle plate. Typically the pressure ranges between about 0.01 mTorr to about 100 mTorr during the deposition (or deposition-etch) process.

An intense magnetic field is produced by electromagnets 209b within the cathode target region. The electrons emitted from the cathode are confined by the crossing electric and magnetic fields within the hollow portion of the cathode target 211 to form a region of high plasma density within the hollow cathode. Additional electromagnets 209c-209e are arranged downstream of the cathode target and are used to shape and further confine the plasma at the elevations closer to the wafer pedestal 203.

In certain embodiments, a system controller 225 is employed to control process conditions during the deposition process, insert and remove wafers, etc. The controller will typically include one or more memory devices and one or more processors. The processor may include a CPU or computer, analog and/or digital input/output connections, stepper motor controller boards, etc.

In certain embodiments, the controller controls all of the activities of the apparatus. The system controller executes system control software including sets of instructions for controlling the timing, mixture of gases, chamber pressure, chamber temperature, wafer temperature, RF power levels at the wafer (if any), DC power levels at the target, polarity of electromagnetic coils 209a-e, current levels applied to the coils, grounding of the shields, pedestal position, and other parameters of a particular process. Other computer programs stored on memory devices associated with the controller may be employed in some embodiments.

Typically there will be a user interface associated with controller 225. The user interface may include a display screen, graphical software displays of the apparatus and/or process conditions, and user input devices such as pointing devices, keyboards, touch screens, microphones, etc.

The computer program code for controlling the deposition process can be written in any conventional computer readable programming language: for example, assembly language, C, C++, Pascal, Fortran or others. Compiled object code or script is executed by the processor to perform the tasks identified in the program.

The controller parameters relate to process conditions such as, for example, magnetic field within the chamber, plasma density within the chamber, process gas composition and flow rates, temperature, pressure, plasma conditions such as DC power levels, grounding of the shields, cooling gas pressure, and chamber wall temperature. These parameters are provided to the user in the form of a recipe, and may be entered utilizing the user interface.

Signals for monitoring the process may be provided by analog and/or digital input connections of the system controller. The signals for controlling the process are output on the analog and digital output connections of the deposition apparatus.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A plasma control program may include code for setting shield grounding, DC power levels applied to the target, as well as polarity parameters and current levels applied to different electromagnetic coils in an apparatus. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in pedestal or chuck. Appropriately programmed feedback and control algorithms may be used with data from these sensors to maintain desired process conditions.

In various embodiments, the controller includes program instructions for implementing methods described herein. Accordingly, the apparatus may be specifically configured to perform the methods described herein. As such, the controller may be programmed with instructions specifying parameters for generating a discharge plasma in which the properties of the plasma are controlled by modifying the grounding path of the plasma. For example, in an apparatus in which the grounding shields are configured as an array of switched shields having different surface area and location relative to the wafer support, the controller may comprise program instructions for switching between float and ground one or more grounding shields in the array, as further described below. Or, in an apparatus in which the grounding shields are configured as at least two shields, one of which is grounded and the other having variable resistance to ground, the controller may comprise program instructions for varying resistance to ground of the variable grounding shield, as further described below.

During deposition in a plasma PVD apparatus, according to one implementation, the wafer substrate is placed into the process chamber, which is configured for plasma generation. The process chamber includes a metal target which accepts a negative DC bias and serves as a source of metal flux during deposition; a wafer pedestal which holds the wafer in position during material processing and which also provides temperature control of the wafer; an inlet for introduction of an inert gas; and one or several magnets for confining the plasma in the proximity of the target. An RF bias can be optionally applied to the wafer; however application of RF bias is not necessary and its absence is actually preferred in many embodiments of the invention.

After the wafer substrate is secured on the wafer pedestal, and the inert gas (e.g., argon) is introduced into the chamber, the plasma is ignited by applying a DC power to the target and confined with the use of magnetic field in the proximity of the target. Argon is positively ionized in the plasma to form Ar⁺ ions which impinge on a negatively biased target with sufficient energy to dislodge metal atoms from the target. The neutral metal atoms dislodged from the target can become ionized in the plasma. The metal species including neutrals and ions are subsequently deposited on the wafer surface.

The positively charged argon ions and metal ions, under certain conditions, may acquire sufficient energy at the wafer surface to dislodge material from the wafer surface causing etching. Atoms from the etched material may be permanently removed from the wafer, or may be redistributed from one position on the wafer to a different position. For example, material may be redistributed from the bottom of the via to the via sidewalls. Typically, etch and deposition processes occur simultaneously in the PVD chamber. Etching is performed by the inert gas ions and, in some cases, by metal ions, impinging on the wafer with sufficient energy to dislodge the exposed material, while deposition is effected by neutral metal atoms and, in some cases, by metal ions, being sputtered onto the wafer from the target. When an intrinsic etch rate E is greater than the intrinsic deposition rate D, a net etching process occurs on the wafer surface. When the etch rate E is smaller than the deposition rate D, the process is characterized as a net deposition.

In general, a variety of PVD conditions are suitable for PVD deposition and PVD etch operations. For the net deposition process the DC power can range from about 5 W/(cm² target) to 25 W/(cm² target), and, for the RF power, from about 0 W/(cm² substrate) to 0.5 W/(cm² substrate). PVD deposition is described in U.S. Pat. Nos. 6,905,959; 6,773,571; and 6,642,146, which patents are hereby incorporated by reference in their entireties and for all purposes, in particular for their disclosure of general PVD deposition and etch parameters applicable in the context of the present invention.

When net deposition of material is desired, the grounding shields providing the ground surface in the reactor process chamber are configured to modulate the E/D ratio and self-sputtering rate lower, as described herein. When net etch of material is desired, the grounding shields providing the ground surface in the reactor process chamber are configured to modulate the E/D ratio and self-sputtering rate higher, as described herein.

In accordance with the present invention, the self-sputtering rate, and hence the E/D ratio of a deposition plasma is controlled by modifying the grounding path (e.g., the DC grounding surface's (shields in PVD chamber) location, shape and/or area). In particular embodiments, this is accomplished by, instead of using a single piece of grounding shield or electrically connected shields, using plurality of shields that are electrically insulated from each other. These shields can be either floated or grounded or a combination through electrical circuit control. The self-sputtering rate and E/D ratio can be varied to increase the deposition or etch component of the plasma flux by varying the grounding of the plurality of shields. In the absence of RF biasing, the bias on the substrate is solely due to the substrate floating potential thereby generating a narrow ion energy distribution.

Referring to FIG. 3, a particular embodiment of a shield configuration in accordance with the present invention is illustrated in top plan view and cross-section. In this embodiment, four coaxial grounding shields are deployed in the reactor process chamber around and above the pedestal wafer support and below the target. Each of the shields is electrically isolated from the others. DC switches determine which of the shields is grounded or floated, and when. During a deposition or etch operation, at least one of the shields is grounded. When all of the shields are switched to ground, ions incident on the deposition substrate have lower energy. The self-sputtering rate and E/D ratio of the plasma flux are low accordingly. This is typical of a deposition condition, particularly for a recessed feature with a low aspect ratio. In contrast, the ion energy is higher if only the smallest piece of shield (i.e., shield 4) is grounded, which in turn leads to higher E/D ratio. The E/D ratio can be modulated between the above two extreme cases in order to achieve the desired E/D ratio and self-sputter rate for a particular deposition application.

Referring to FIG. 4, an alternative embodiment of a shield configuration in accordance with the present invention is illustrated in cross-section. In this embodiment, a fixed shield that has variable resistance to ground, for example via a potentiometer, is used in conjunction with a permanently grounded shield. The permanently grounded shield is present to ensure a low resistance current path to sustain the discharge. The potentiometer on the second shield can be adjusted to change the ratio of the return current going to the first shield relative to the second shield, thereby varying the resistance to ground of the variable grounding shield. Following the same principle as in the shield array embodiment described above with reference to FIG. 3, continuous wafer bias adjustment within a certain range can be achieved via modulating the potentiometer setting instead of having discrete and finite settings by switching between different combinations of multiple shields. In this way, the E/D ratio can be modified in order to achieve the desired E/D ratio and self-sputtering rate for a particular deposition application.

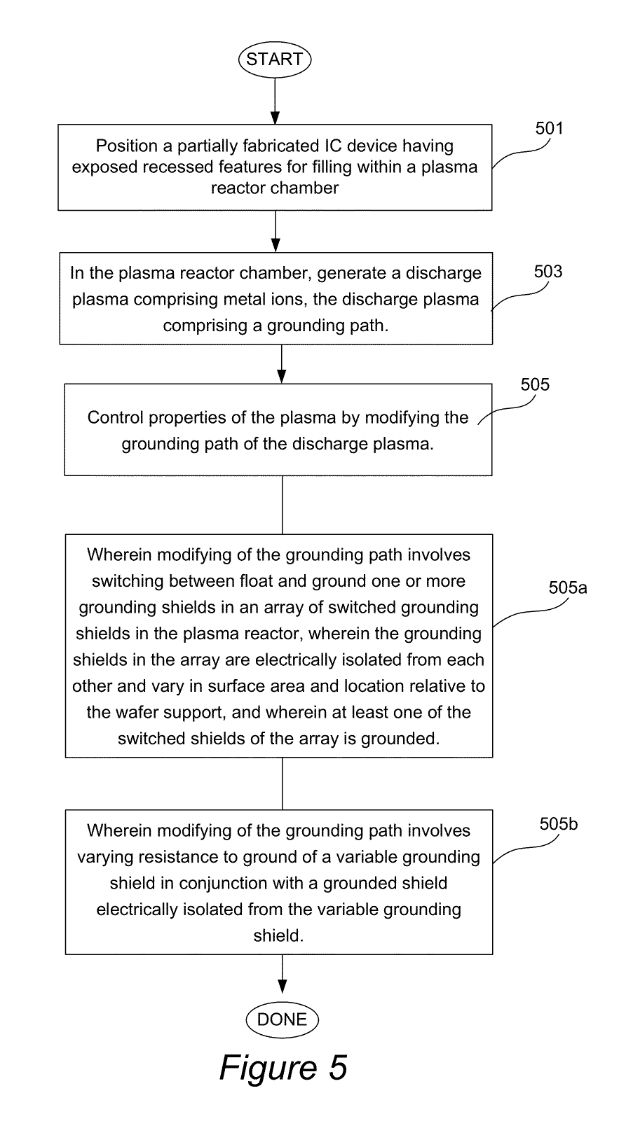

FIG. 5 depicts a process flow diagram in accordance with the present invention including these embodiments. In operation 501, a partially fabricated IC device having exposed recessed features for filling is positioned within a plasma reactor chamber. In operation 503, in the plasma reactor chamber, a discharge plasma comprising metal ions is generated, the discharge plasma comprising a grounding path. In operation 505, properties of the plasma are controlled by modifying the grounding path of the discharge plasma. The recessed features can then be completely or partially filled by plasma deposition. In not all, but in preferred embodiments, the plasma deposition is conducted without RF bias, and the reactor does not have an RF system.

The figure also depicts alternative embodiments for the configuration of the plurality of shields for the modifying of the grounding path. In 505a, the modifying of the grounding path involves switching between float and ground one or more grounding shields in an array of switched grounding shields in the plasma reactor, wherein the grounding shields in the array are electrically isolated from each other and vary in surface area and location relative to the wafer support, and wherein at least one of the switched shields of the array is grounded. Alternatively, in 505b, the modifying of the grounding path comprises varying resistance to ground of a variable grounding shield in conjunction with a grounded shield electrically isolated from the variable grounding shield.

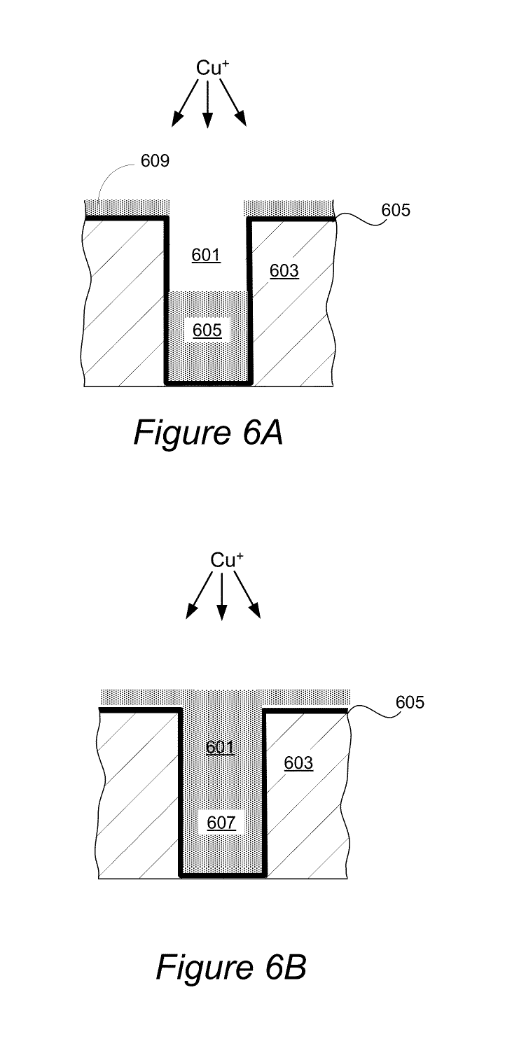

Depending on the deposition application, the E/D ratio and self-sputtering rate may be set by modifying the grounding path of the plasma and then fixed for the duration of the entire deposition. This may be appropriate, for example, for a wider recessed feature with a low aspect ratio, such as 3:1, 2:1, 1:1 or even lower. For such a feature, a fixed E/D ratio plasma deposition may be conducted in accordance with the present invention without the formation of voids. FIGS. 6A-6B show cross-sectional views of device structures during PVD metal fill in accordance with an embodiment of this aspect of the invention. In FIG. 6A, a low aspect ratio (e.g., about 2:1) feature 601 in an IC device substrate 603 is shown partially filled with metal 607 deposited by non-RF biased ionized plasma PVD process in accordance with the present invention. The feature may be an interconnect. The copper is deposited over a diffusion barrier layer 605 residing in the feature and on the adjacent field 609. The E/D ratio is set to achieve efficient feature fill without damaging the underlying substrate 603 or barrier 605 by modifying the grounding path of the plasma at the outset, and then remains fixed for the entire deposition. Copper is deposited both within the recessed feature 601 and on the field region 609, ultimately resulting in a structure shown in FIG. 6B. To prevent shorting between adjacent interconnects, all conductive material residing on the field (which includes both copper overburden and diffusion barrier residing on the field) is subsequently removed from the field region by a planarization operation such as CMP. In this way, void-free gapfill of a recessed feature on an IC device substrate may be achieved without damage to the underlying substrate or barrier, and without changing the deposition parameters during the gapfill operation.

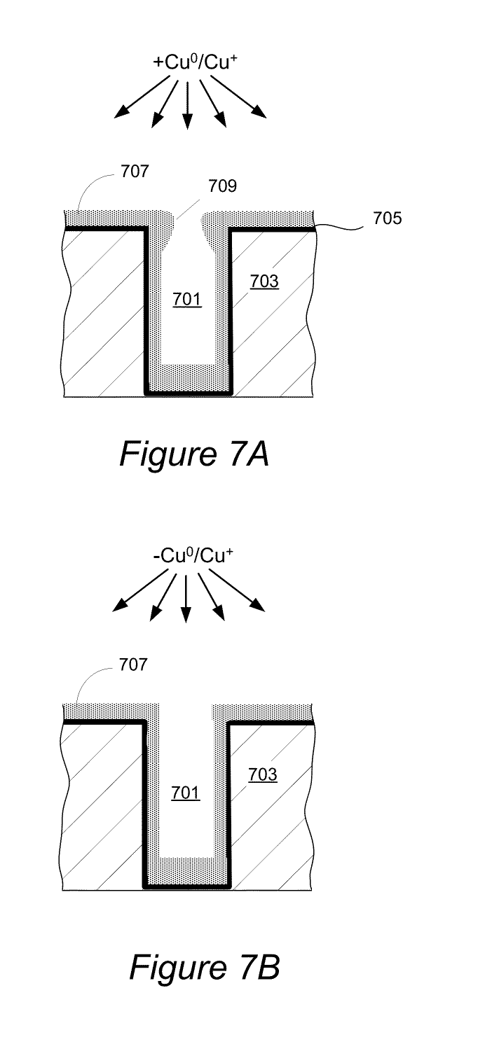

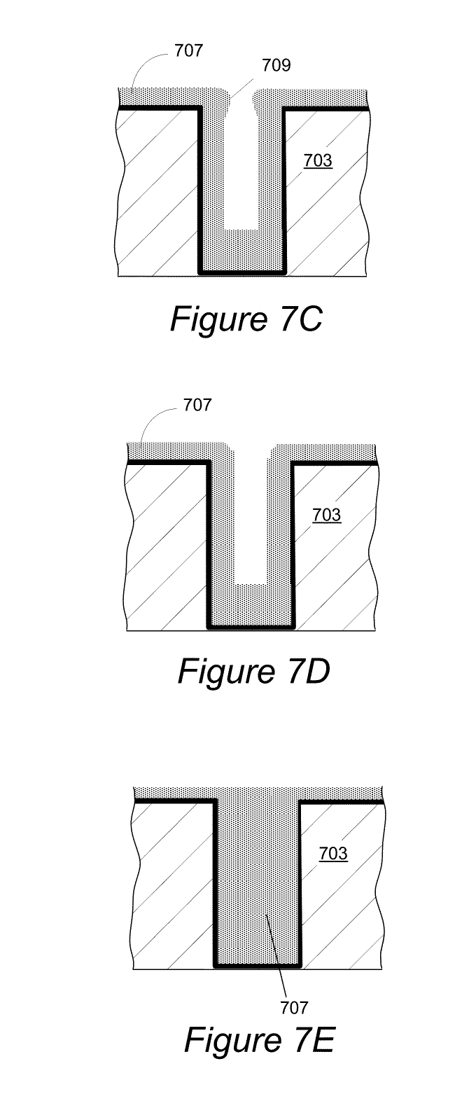

Alternatively, the E/D ratio may be dynamically altered during deposition in accordance with the present invention in order to change from a deposition to an etch condition to achieve high quality feature fill (e.g., without voids). Such an alternative process is generally applicable to narrow, high aspect ratio feature fill, such as 5:1 or greater. For such high aspect ratio features, the E/D ratio can be modulated by modifying the grounding path of the plasma between lower and higher E/D ratios during the course of the deposition so that any overhang that develops at the feature opening during a period of low E/D ratio can be removed during a period of high E/D ratio to permit complete, void-free filling of the feature. FIGS. 7A-7E show cross-sectional views of device structures during PVD metal fill in accordance with an embodiment of this aspect of the invention. In FIG. 7A, a high aspect ratio (e.g., about 8:1 (not shown to scale)) feature 701 in an IC device substrate 703 is shown partially filled with metal 707 deposited by non-RF biased ionized plasma PVD process in accordance with the present invention. The feature may be an interconnect. The copper is deposited over a diffusion barrier layer 705 residing in the feature and on the adjacent field. The E/D ratio is initially set to achieve efficient feature fill without damaging the underlying substrate 703 or barrier 705 by modifying the grounding path of the plasma at the outset. After a portion of the gap has been filled, an overhang 709 begins to form at the feature (gap) opening.

At this point, the E/D ratio is modulated higher by modifying the deposition plasma's grounding path, for example the location and surface area of grounding shields provided in the reactor process chamber. The enhanced etch component of the plasma flux results in net removal of overhang material to widen the feature opening for further fill, as shown in FIG. 7B. Then, the E/D ratio is modulated lower again by again modifying the deposition plasma's grounding path, resulting in additional gapfill and overhang formation due to the enhanced deposition component of the plasma flux, as shown in FIG. 7C. The E/D ratio is then again modulated higher by again modifying the deposition plasma's grounding path, and the enhanced etch component of the plasma flux results in net removal of overhang material to again widen the feature opening for further fill, as shown in FIG. 7D. These E/D ratio modifications may be repeated as many times as are necessary to achieve void-free gapfill. FIG. 7E shows complete gapfill in accordance with this embodiment of the present invention.

As in the prior embodiment, to prevent shorting between adjacent interconnects, all conductive material residing on the field (which includes both copper overburden and diffusion barrier residing on the field) is subsequently removed from the field region by a planarization operation such as CMP. In this way, void-free gapfill of a recessed feature on an IC device substrate may be achieved without damage to the underlying substrate or barrier, by dynamically altering the deposition parameters during the gapfill operation.

Control of E/D ratio and self-sputtering rate solely by modifying the plasma grounding path results in a narrow ion energy distribution in the plasma flux, and decreases the likelihood of substrate damage due to a high energy “tail.” RF biasing of the substrate is not necessary, and generally not preferred. Even if RF biasing is used in conjunction with grounding control, the ion energy distribution can be narrowed by decreasing the RF power.

The apparatus/process described herein above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Process modulations, such as E/D ratio, and therefore gapfill performance, can be achieved by modifying a deposition plasma's grounding path, for example the location and surface area of grounding shields provided in the reactor process chamber. The self-sputtering rate and actual E/D ratio can be modulated by adjusting the grounding surface's location, shape and/or area. And unlike RF induced sputtering, self-sputtering has narrow ion energy distribution, which provides better process controllability and larger process window for integration.

In particular embodiments, control of plasma properties by modifying the grounding path of the plasma can be conducted with or without application of RF bias. Even in conjunction with the application of RF bias, self-sputtering induced by grounding path modulation narrows the incident ion energy distribution, decreasing the likelihood of damage to underlying structures during deposition-etch processing. RF may also be completely eliminated, with the resulting benefit of reducing reactor cost and complexity while providing more uniform incident ion energy distribution for improved performance.

Although various details have been omitted for clarity's sake, various design alternatives may be implemented. Therefore, the present examples are to be considered as illustrative and not restrictive, and the invention is not to be limited to the details given herein, but may be modified within the scope of the appended claims.

What is claimed is:

1. A plasma deposition method, comprising:
in a plasma reactor, generating a discharge plasma comprising metal ions, the discharge plasma comprising a grounding path; and
controlling properties of the plasma by modifying the grounding path of the discharge plasma.

2. The method of claim 1, wherein the modifying of the grounding path comprises switching between float and ground one or more grounding shields in an array of switched grounding shields in the plasma reactor, wherein the grounding shields in the array are electrically isolated from each other and vary in surface area and location relative to a substrate support in the plasma reactor, and wherein at least one of the switched shields of the array is grounded.

3. The method of claim 1, wherein the modifying of the grounding path comprises varying resistance to ground of a variable grounding shield in conjunction with a grounded shield electrically isolated from the variable grounding shield.

4. The method of claim 3, wherein the grounding of the variable grounding shield is controlled by adjustment of a potentiometer.

5. The method of claim 1, further comprising positioning a partially fabricated IC device substrate having exposed recessed features for filling within the plasma reactor process chamber, and at least partially filling the recessed features with the metal species of the plasma.

6. The method of claim 5, wherein no substantial substrate damage occurs.

7. The method of claim 6, wherein the metal is copper.

8. The method of claim 7, wherein the features are filled void-free.

9. The method of claim 1, wherein the controlled plasma properties comprise at least one property selected from the group consisting of E/D ratio, self-sputtering rate and energy distribution of metal ions of the plasma flux.

10. The method of claim 1, wherein the properties of the plasma are controlled without application of RF bias.

11. The method of claim 1, wherein the properties of the plasma are controlled solely by modifying the grounding path of the discharge plasma.

12. The method of claim 1, wherein the discharge plasma is a DC discharge plasma.

13. The method of claim 1, wherein the plasma reactor comprises a hollow cathode magnetron.

14. The method of claim 1, wherein the metal ions of the plasma flux have a substantially uniform energy distribution.

15. The method of claim 1, wherein an E/D ratio and self-sputtering rate of the plasma flux are set by modifying the grounding path of the plasma and then fixed during the deposition.

16. The method of claim 1, wherein the E/D ratio is modulated by modifying the grounding path of the plasma between lower and higher E/D ratios during the course of the deposition.

17. A plasma deposition apparatus, comprising:
a processing chamber;
a deposition substrate support;
a metal ion discharge plasma source;
a plurality of grounding shields, the grounding shields configured to control properties of the discharge plasma by modifying the grounding path of the discharge plasma.

18. The apparatus of claim 17, wherein the plurality of shields comprises switching an array of switched grounding shields in the plasma reactor, wherein the grounding shields in the array are electrically isolated from each other and vary in surface area and location relative to the substrate support, and wherein at least one of the switched shields of the array is grounded.

19. The apparatus of claim 17, wherein the plurality of shields comprises a variable grounding shield in conjunction with a grounded shield electrically isolated from the variable grounding shield.

20. The apparatus of claim 19, further comprising a potentiometer operatively connected to the variable grounding shield.

21. The apparatus of claim 17, further comprising a metal target.

22. An apparatus for filling recessed features on a wafer substrate, comprising:
(a) a process chamber configured to hold a metal target;
(b) a wafer support for holding the wafer in position during deposition of a metal-containing material; and
(c) a controller comprising program instructions for generating a discharge plasma comprising metal ions in the process chamber, the discharge plasma comprising a grounding path, and controlling properties of the plasma by modifying the grounding path of the discharge plasma.
